(19) United States
(12) Patent Application Publication
(10) Pub. No.: US 2019/0059173 A1
(43) Pub. Date: Feb. 21, 2019

(54) An Equipment Displacement System for a Containerised Data Centre

(71) Applicant: THE DATA EXCHANGE NETWORK LTD, Perth, Western Australia (AU)

(72) Inventors: Timothy Mark Desmond, Perth, Western Australia (AU); Dean Coetzee, Ocean Reef, Western Australia (AU); Bill Pope, Pukemoremore (NZ)

(21) Appl. No.: 15/763,880

(22) PCT Filed: Jul. 30, 2016
(86) PCT No.: PCT/AU2016/050691

§ 371 Date: Mar. 28, 2018

(30) Foreign Application Priority Data
Sep. 29, 2015 (AU) 2015903967

(51) Int. Cl. H05K 7/14

(52) U.S. Cl. CPC H05K 7/1497; G01V 8/10

(57) ABSTRACT

Provided is an equipment displacement system (12) for a containerised data centre (14). The system (12) comprises at least one platform (16) which is configured to operatively receive equipment (18). In a preferred example the system (12) typically comprises two platforms (16). The system (12) further generally comprises a guide (20) which operatively mounts each platform (16) onto an equipment mounting surface (22) of a container (10). Each guide (20) is configured for guiding a platform (16) between opposing sides (24.1) and (24.2) of the container (10).

### TECHNICAL FIELD

This invention relates to an equipment displacement system for a containerised data centre, and a containerised data centre with such an equipment displacement system.

### BACKGROUND ART

The following discussion of the background art is intended to facilitate an understanding of the present invention only. The discussion is not an acknowledgement or admission that any of the material referred to is or was part of the common general knowledge as at the priority date of the application.

The Internet can be defined as a global network of peers or peering points that interconnect between each other. As such, the Internet is made up of many such networked peering points which can be connected to by users for the consumption of content and online services. These peering points are typically known as data centres (DCs) or Internet exchanges (IXs) and are where thousands, sometimes hundreds of thousands of computers (servers), are housed in secure, mostly specially built, facilities for access by users.

By providing more peering points and Internet exchanges, the Internet's resiliency and capacity are increased, allowing more connections and consumption of content and services by users. This increase in consumption and access is driving a shift in the construction requirements for these special facilities, particularly where cost, practicality and availability are concerned.

The conventional approach to existing data centre design, construction and operation provides numerous shortcomings, as a data centre may be a custom designed and built facility, requiring time, effort and increased cost. Where some manner of modular data centre exists, such as containerised data centres, there is often no accepted standards or uniformity with regard to the design and/or equipment capabilities.

Similarly, containerised data centres, whilst overcoming numerous logistical problems faced by conventional data centres, have the drawback of very limited maintenance access and working space. Computer and associated equipment that is required to build a containerised data centre often leaves very limited space once installed inside a container, making such a standardised containerised build ineffective.

There exists a need for a modularised data centre design with suitable configurations around equipment and capability. The following invention seeks to propose possible solutions, at least in part, to the known shortcomings in the art.

### SUMMARY OF THE INVENTION

It is to be appreciated that reference herein to a ‘container’ generally refers to any manner of intermodal container, such as a standardized shipping container, a cargo or freight container, an ISO container, a so-called shipping, sea or ocean container, a container van or box, a Conex box, or the like. Accordingly, ‘containerised’ refers to any arrangement, equipment or gear that has been specifically adapted, modified or configured for placement or installation within such a container.

According to a first aspect of the invention there is provided an equipment displacement system for a containerised data centre, said system comprising:

at least one platform configured to operatively receive equipment;

a guide mounting said at least one platform onto an equipment mounting surface of a container, said guide configured for guiding a platform between opposing sides of the container;

at least one actuator configured to displace a platform as guided; and

a control system for controlling the actuator, said control system configured to monitor a position of said at least one platform within the container and to stop the actuator should any foreign body obstruct a guide, wherein the displacement system facilitates maintenance access to either side of the equipment within the container.

In one example, the system comprises two platforms with associated guides, each platform and guide occupying roughly one half of an elongate container, the platforms and guides separated by a central access passageway.

Typically, the platforms are configured to receive equipment selected from the group consisting of server racks, data centre gear, electrical supply and distribution equipment, and thermal regulation equipment.

Preferably, each platform is configured to receive a plurality of modular equipment units.

In one example, the equipment mounting surface of the container may include a floor of the container. In another example, the equipment mounting surface of the container may include a roof of the container.

Typically, each guide may comprise a rail-and-wheel or wheel-and-track or belt-and-drive arrangement mounting a platform onto the equipment mounting surface of the container to guide such platform between opposing sides of the container.

Typically, the actuator may comprise any manner of electromechanical, electromagnetic, hydraulic and/or pneumatic actuator configured to displace a platform.

In one example, the actuator comprises an electromechanical drive. Preferably, the actuator comprises a variable speed electromechanical drive.

Typically, the system comprises an actuator for each respective platform.

Typically, the control system may include any central processing unit having electronic circuitry configured to perform basic arithmetic, logical, control and/or input/output (I/O) operations as specified by a set of instructions.

In one embodiment, the central processing unit comprises a programmable logic controller (PLC).

Typically, the control system comprises a sensor arrangement configured to monitor a position of each platform within the container.

Preferably, the sensor arrangement may comprise a light curtain and a distance measurement sensor configured to sense foreign bodies and a distance of a platform to a side of the container.

According to a second aspect of the invention there is provided a containerised data centre having an equipment displacement system with two platforms configured to operatively receive equipment, and a guide mounting each platform onto an equipment mounting surface of an elongate container, said guide configured for guiding a platform between opposing sides of the container, wherein each platform and guide arrangement occupies one end of said container, the platform and guide arrangements separated by a central access passageway, wherein the displacement system facilitates maintenance access to either side of the equipment mounted on the platforms.

Typically, the containerised data centre further comprises at least one actuator configured to displace a platform as guided.

Typically, the containerised data centre further comprises a control system for controlling the actuator, said control system configured to monitor a position of each platform within the container and to stop the actuator should any foreign body obstruct a guide.

Typically, the platforms are configured to receive equipment selected from the group consisting of server racks, data centre gear, electrical supply and distribution equipment, and thermal regulation equipment.

Preferably, each platform is configured to receive a plurality of modular equipment units.

In one example, the equipment mounting surface of the container may include a floor of the container. In another example, the equipment mounting surface of the container may include a roof of the container.

Typically, each guide may comprise a rail-and-wheel or wheel-and-track arrangement mounting a platform onto the equipment mounting surface of the container to guide such platform between opposing sides of the container.

Typically, the actuator may comprise any manner of electromechanical, electromagnetic, hydraulic and/or pneumatic actuator configured to displace a platform.

In one example, the actuator comprises an electromechanical drive. Preferably, the actuator comprises a variable speed electromechanical drive.

Typically, the system comprises an actuator for each respective platform.

Typically, the control system may include any central processing unit having electronic circuitry configured to perform basic arithmetic, logical, control and/or input/output (I/O) operations as specified by a set of instructions.

In one embodiment, the central processing unit comprises a programmable logic controller (PLC).

Typically, the control system comprises a sensor arrangement configured to monitor a position of each platform within the container.

Preferably, the sensor arrangement may comprise a light curtain and a distance measurement sensor configured to sense foreign bodies and a distance of a platform to a side of the container.

According to a third aspect of the invention there is provided a containerised data centre having an equipment displacement system in accordance with the first aspect of the invention.

According to a fourth aspect of the invention there is provided an equipment displacement system for a data centre, said system comprising:

at least one platform configured to operatively receive equipment;

a guide mounting said at least one platform onto an equipment mounting surface of the data centre, said guide configured for guiding a platform between opposing sides of the surface;

at least one actuator configured to displace a platform as guided; and

a control system for controlling the actuator, said control system configured to monitor a position of said at least one platform on the surface and to stop the actuator should any foreign body obstruct a guide, wherein the displacement system facilitates maintenance access to either side of the equipment on the surface of the data centre.

### BRIEF DESCRIPTION OF THE DRAWINGS

Further features of the present invention are more fully described in the following description of several non-limiting embodiments thereof. This description is included solely for the purposes of exemplifying the present invention. It should not be understood as a restriction on the broad summary, disclosure or description of the invention as set out above. The description will be made with reference to the accompanying drawings in which:

FIG. 1 is a perspective diagrammatic representation of one example of a containerised data centre with an equipment displacement system, in accordance with an aspect of the invention;

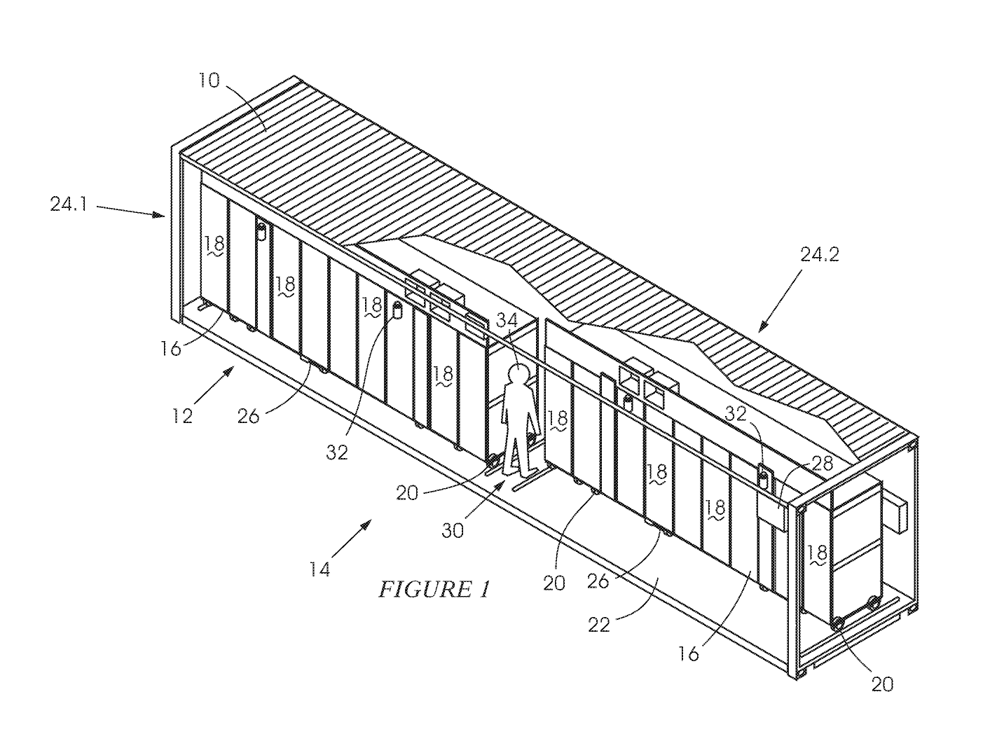

FIG. 2 is a bottom perspective diagrammatic representation of one example of equipment displacement system; and

FIG. 3 is front diagrammatic representation of the equipment displacement system of FIG. 2.

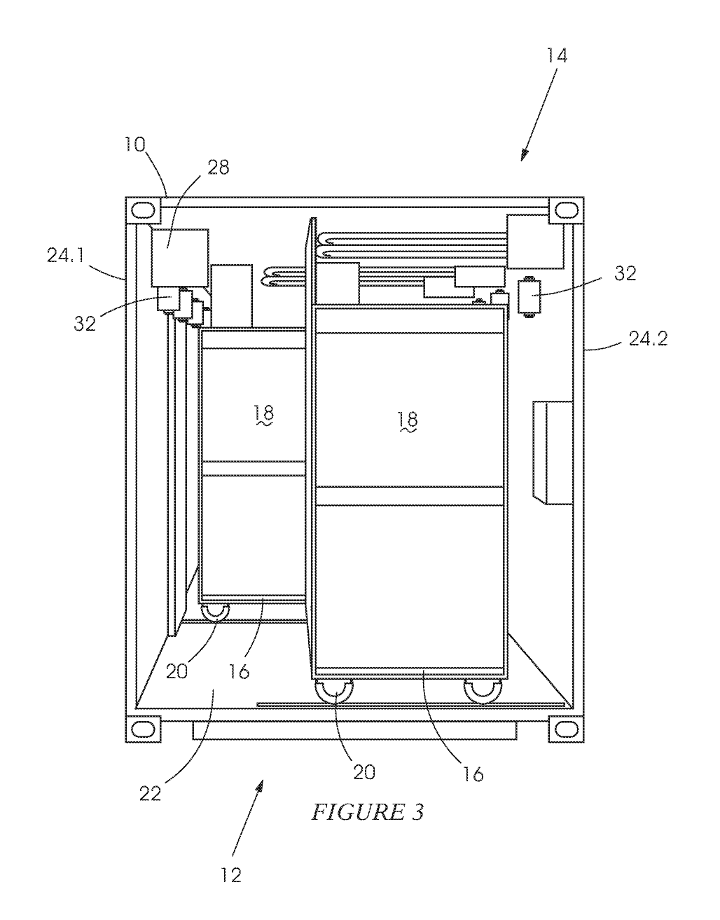

### DESCRIPTION OF EMBODIMENTS

The following modes, given by way of example only, are described in order to provide a more precise understanding of the subject matter of a preferred embodiment or embodiments.

In the figures, incorporated to illustrate features of an example embodiment, like reference numerals are used to identify like parts throughout the figures.

With reference now to the accompanying drawings, there is shown one example of an equipment displacement system 12 for a containerised data centre 14.

In general, the system 12 comprises at least one platform 16 which is configured to operatively receive equipment 18. In a preferred example shown in the figures, the system 12 typically comprises two platforms 16, as shown.

The system 12 further generally comprises a guide which operatively mounts each platform 16 onto an equipment mounting surface 22 of a container 10, as shown. Each guide 20 is configured for guiding a platform 16 between opposing sides 24.1 and 24.2 of the container 10.

It is to be appreciated that other embodiments may comprise a different numbers of platforms 16. For example, one example may feature a single platform 16 with a central access passageway located on one side of the container 10. Alternatively, another example may feature three, or more, platforms 16 with a suitable access passageway 30 located between one or more of such platforms, or the like.

It is further to be appreciated that the equipment mounting surface 22 of the container 10 may include a floor or a roof of the container 10, depending on design requirements. In the shown example, the equipment 18 is mounted to the floor of the container 10 via the platforms 16. However, in a further example, the guides 20 may suspend the platforms 16, with the equipment 18, from the roof of the container 10.

Typically, each platform 16 is configured to receive equipment 18 typically forming a data centre, such as server racks, data centre gear, electrical supply and distribution equipment, and/or thermal regulation equipment, e.g. air-conditioning units, etc. In a preferred embodiment, each platform 16 is configured to receive a plurality of modular equipment units 18, as shown. For example, the platforms 16 may define suitable attachment or fastening points for receiving the equipment 18, or the like.

In the exemplified mode, each platform 16 and guide arrangement occupies roughly one half of the elongate container 10, as shown, with the two platforms 16 and their associated guides 20 separated by a central access passageway 30.

In one example, each guide 20 comprises a rail-and-wheel or wheel-and-track arrangement which mounts the respective platforms 16 onto the equipment mounting surface 22 of the container 10, i.e. floor or roof. In this manner, the guide 20 is able to guide or restrict displacement of a platform 16 between opposing sides 24.1 and 24.2 of the container 10, as shown.

Preferably, the system 12 further comprises at least one actuator 26 which is configured to displace a platform 16 as guided by its respective guide 20. The actuator 26 may comprise any manner of electromechanical, electromagnetic, hydraulic and/or pneumatic actuator configured to displace a platform 16. In this example, the actuator 26 comprises an electromechanical drive, such as a variable speed electromechanical drive, or the like.

In one example, the system 12 comprises an actuator for each respective platform 16. However, in another embodiment, the system 12 may include one actuator 26 having suitable linkages with each respective platform 16, or the like.

In a preferred embodiment, the system 12 also includes a control system 28 configured for controlling the actuator 26. In addition, the control system 28 is typically further configured to monitor a position of each platform 16 within the container 10 and to stop the relevant actuator 26 should any foreign body obstruct a guide 20.

For example, a foreign body may include anything which is in the way of a platform 16 being moved from one side 24.1 of the container 10 to the other side 24.2, such as a user 34, tools, etc.

As such, the control system 28 typically includes any suitable central processing unit having electronic circuitry configured to perform basic arithmetic, logical, control and/or input/output (I/O) operations as specified by a set of instructions. In a preferred embodiment, the central processing unit comprises a programmable logic controller (PLC), or the like.

In addition, the control system 28 generally comprises a sensor arrangement 32 which is configured to monitor a position of each platform 16 within the container 10. For example, the sensor arrangement 32 may comprise a light curtain and a distance measurement sensor configured to sense any foreign bodies in the path of a platform 16 as it is being moved, as well as a distance of a platform 16 to a side 24 of the container 10, or the like.

The control system 28 is typically user-activated by means of a suitable activator, such as a switch. For example, a user 34 enters the container 10 by means of the central access passage 30 to perform maintenance on a server rack 18 housed on one of the platforms 16.

Such maintenance requires access to both sides of the relevant server rack 18. By the system 12 being able to move each platform 16 to either side 24 of the container, allows the user 34 access to both sides of a server rack 18, without requiring a dedicated access passageway down the length of the container 10.

This is particularly advantageous, as standard sized server racks 18 can be housed in a container 10, without requiring changes to the container 10, whilst allowing maintenance access to either side of the server equipment 18.

A user 34 is able to work and service one side of the equipment 18, then move back to the central access passage 30, activate the control system 28 to move or displace the relevant platform 16 from one side 24.1 of the container 10 to the other side 24.2, as described above.

Once the relevant platform 16 has been moved, the other side of the equipment 18 is now accessible by walking down the passage formed after the platform 16 has been moved to the other side 24.2 of the container 10. In this manner, the displacement system 12 facilitates maintenance access to either side of the equipment 18 within the container 10.

In addition, the control system 28 is able to ensure the safety and integrity of the equipment and the user 34 by monitoring anything in the path of the moving platform 16 by means of the sensor arrangement 32. If a foreign body, such as the user or tools, is sensed, the actuator prevents or stops movement of the platform 16 by stopping the relevant actuator 26.

The invention also encompasses a containerised data centre 14 which includes an equipment displacement system 12, as described above.

In the above-described manner, the invention is able to provide an automated system 12 for moving an array of server/equipment racks 18 within a standard ISO shipping container 10 to increase the working space in either the front or back positions of the respective equipment 18.

In one example, the system 12 consists of the platforms 16 or mounting plates designed to attach to the server racks 18 securely. This floor plate system is modular and the platforms or plates 16 can be changed out to allow different sized racks 18 to be placed in line with the other racks.

This configuration allows different kinds of equipment 18 to be installed within the container 10, or additional cooling or power protection or distribution equipment to be installed, or the like. As shown, one platform 16 can be moved to one side 24.1 of the container 10 to allow increased access to the front or back of the racks 18.

In one example, the entire floor section or platform 16, each made of up to 9 600 mm wide or standard 19″ server racks and cooling equipment, moves with one actuator in the form of a variable speed drive (VSD) electric motor, which is attached to a drive shaft to drive the various wheels of the guide 20. The floor of the container 10 includes tracks and a shaped wheel which runs inside a groove of the track, similar to a train track.

The VSD is programmed via a PLC and safety PLC system, comprising the control system 28, which includes light safety curtains and light distance measurement devices or sensor arrangement 32 to ensure the floor platform 16 is always in the correct position.

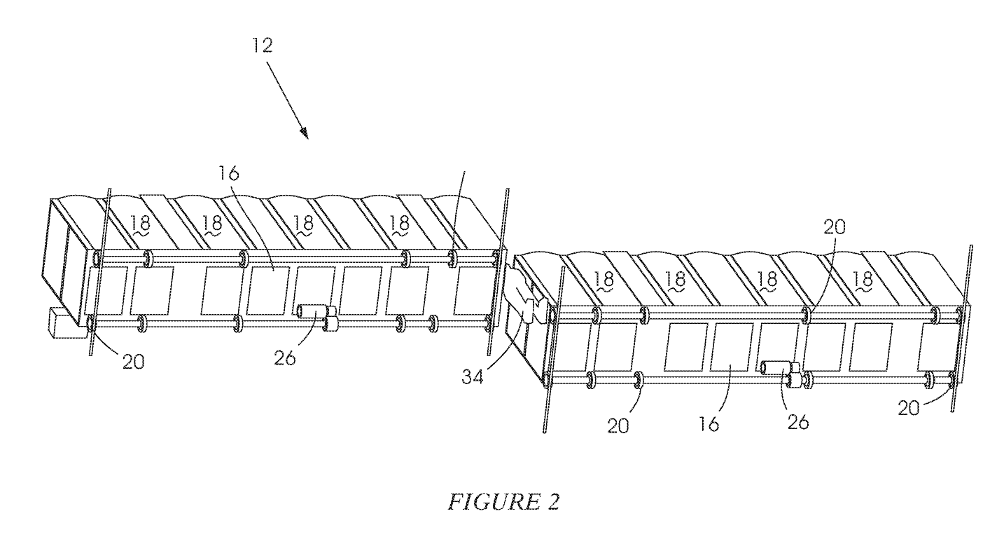

As shown in FIG. 2, an underside of the floor plates or platforms 16 can be seen along with drive shafts, wheels (each wheel is individually aligned in a track—only four shown) and the centrally mounted VSD electric motor 26, essentially comprising the guides 20 with actuator 26, as described above.

It is to be appreciated that the system 12 may also be used in other data centre configurations and is not limited to only containerised data centres. For example, the system 12 can be used in conventional data centres installed inside a building, or the like.

The Applicant believes it particularly advantageous that the system 12 allows controlled displacement of entire floor pieces or platforms 16, with equipment 18 mounted thereon, within anyone of the standard container sizes 10. By being able to construct a data centre within the confines of a standard shipping container 10 means that it is logistically easier and considerably less costly to build, handle and deploy such containerised data centres 14. Similarly, the system 12 may also find application in other data centres where space is limited.

Optional embodiments of the present invention may also be said to broadly consist in the parts, elements and features referred to or indicated herein, individually or collectively, in any or all combinations of two or more of the parts, elements or features, and wherein specific integers are mentioned herein which have known equivalents in the art to which the invention relates, such known equivalents are deemed to be incorporated herein as if individually set forth.

It is to be appreciated that reference to “one example” or “an example” of the invention is not made in an exclusive sense. Accordingly, one example may exemplify certain aspects of the invention, whilst other aspects are exemplified in a different example. These examples are intended to assist the skilled person in performing the invention and are not intended to limit the overall scope of the invention in any way unless the context clearly indicates otherwise.

It is to be understood that the terminology employed above is for the purpose of description and should not be regarded as limiting. The described embodiment is intended to be illustrative of the invention, without limiting the scope thereof. The invention is capable of being practised with various modifications and additions as will readily occur to those skilled in the art.

Various substantially and specifically practical and useful exemplary embodiments of the claimed subject matter are described herein, textually and/or graphically, including the best mode, if any, known to the inventors for carrying out the claimed subject matter. Variations (e.g. modifications and/or enhancements) of one or more embodiments described herein might become apparent to those of ordinary skill in the art upon reading this application.

The inventor(s) expects skilled artisans to employ such variations as appropriate, and the inventor(s) intends for the claimed subject matter to be practiced other than as specifically described herein. Accordingly, as permitted by law, the claimed subject matter includes and covers all equivalents of the claimed subject matter and all improvements to the claimed subject matter. Moreover, every combination of the above described elements, activities, and all possible variations thereof are encompassed by the claimed subject matter unless otherwise clearly indicated herein, clearly and specifically disclaimed, or otherwise clearly contradicted by context.

The use of any and all examples, or exemplary language (e.g., “such as”) provided herein, is intended merely to better illuminate one or more embodiments and does not pose a limitation on the scope of any claimed subject matter unless otherwise stated. No language in the specification should be construed as indicating any non-claimed subject matter as essential to the practice of the claimed subject matter.

The use of words that indicate orientation or direction of travel is not to be considered limiting. Thus, words such as “front”, “back”, “rear”, “side”, “up”, down”, “upper”, “lower”, “top”, “bottom”, “forwards”, “backwards”, “towards”, “distal”, “proximal”, “in”, “out” and synonyms, antonyms and derivatives thereof have been selected for convenience only, unless the context indicates otherwise. The inventor(s) envisage that various exemplary embodiments of the claimed subject matter can be supplied in any particular orientation and the claimed subject matter is intended to include such orientations.

The use of the terms “a”, “an”, “said”, “the”, and/or similar referents in the context of describing various embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Moreover, when any number or range is described herein, unless clearly stated otherwise, that number or range is approximate. Recitation of ranges of values herein are merely intended to serve as a shorthand method of referring individually to each separate value falling within the range, unless otherwise indicated herein, and each separate value and each separate sub-range defined by such separate values is incorporated into the specification as if it were individually recited herein. For example, if a range of 1 to is described, that range includes all values there between, such as for example, 1.1, 2.5, 3.335, 5, 6.179, 8.9999, etc., and includes all sub-ranges there between, such as for example, 1 to 3.65, 2.8 to 8.14, 1.93 to 9, etc.

Accordingly, every portion (e.g., title, field, background, summary, description, abstract, drawing figure, etc.) of this application, other than the claims themselves, is to be regarded as illustrative in nature, and not as restrictive; and the scope of subject matter protected by any patent that issues based on this application is defined only by the claims of that patent.

1-31. (canceled)

32. A containerised data centre having an equipment displacement system with two platforms configured to operatively receive equipment, and a guide mounting each platform onto an equipment mounting surface of an elongate container, said guide configured for guiding a platform between opposing sides of the container, wherein each platform and guide arrangement occupies one end of said container, the platform and guide arrangements separated by a central access passageway, wherein the displacement system facilitates maintenance access to either side of the equipment mounted on the platforms.

33. The containerised data centre of claim 32, comprising at least one actuator configured to displace a platform as guided.

34. The containerised data centre of claim 32, comprising a control system for controlling the actuator, said control system configured to monitor a position of each platform within the container and to stop the actuator should any foreign body obstruct a guide.

35. The containerised data centre of claim 32, wherein the platforms are configured to receive equipment selected from the group consisting of server racks, data centre gear, electrical supply and distribution equipment, and thermal regulation equipment.

36. The containerised data centre of claim 32, wherein each platform is configured to receive a plurality of modular equipment units.

37. The containerised data centre of claim 32, wherein the equipment mounting surface of the container includes a floor of the container.

38. The containerised data centre of claim 32, wherein the equipment mounting surface of the container includes a roof of the container.

39. The containerised data centre of claim 32, wherein each guide comprises a rail-and-wheel, wheel-and-track or belt-and-drive arrangement mounting a platform onto the equipment mounting surface of the container to guide such platform between opposing sides of the container.

40. The containerised data centre of claim 32, wherein the actuator comprises an electromechanical drive.

41. The containerised data centre of claim 40, wherein the actuator comprises a variable speed electromechanical drive.

42. The containerised data centre of claim 32, which comprises an actuator for each respective platform.

43. The containerised data centre of claim 32, wherein the control system includes any central processing unit having electronic circuitry configured to perform basic arithmetic, logical, control and/or input/output (I/O) operations as specified by a set of instructions.

44. The containerised data centre of claim 32, wherein the central processing unit comprises a programmable logic controller (PLC).

45. The containerised data centre of claim 32, wherein the control system comprises a sensor arrangement configured to monitor a position of each platform within the container.

46. The containerised data centre of claim 45, wherein the sensor arrangement comprises a light curtain and a distance measurement sensor configured to sense foreign bodies and a distance of a platform to a side of the container.
